(19) United States
(12) Patent Application Publication
(10) Pub. No.: US 2025/0113694 A1
(43) Pub. Date: Apr. 3, 2025

(54) DISPLAY APPARATUS AND LIGHT SOURCE APPARATUS THEREOF

(71) Applicant: SAMSUNG ELECTRONICS CO., LTD., Suwon-si (KR)

(72) Inventors: Hyungsuk KIM, Suwon-si (KR); Sungyeol KIM, Suwon-si (KR); Chunsoon PARK, Suwon-si (KR); Youngmin LEE, Suwon-si (KR); Hyukjun JANG, Suwon-si (KR)

(73) Assignee: SAMSUNG ELECTRONICS CO., LTD., Suwon-si (KR)

(21) Appl. No.: 18/962,833

(22) Filed: Nov. 27, 2024

Related U.S. Application Data
(63) Continuation of application No. PCT/KR2023/007133, filed on May 25, 2023.

(30) Foreign Application Priority Data
Jul. 22, 2022 (KR) 10-2022-0091347

(51) Int. Cl. H10H 29/856; H10H 20/814; H10H 29/49

(52) U.S. Cl. CPC H10H 29/856; H10H 20/814; H10H 29/49

(57) ABSTRACT

A light source apparatus includes: a reflective sheet having a hole; and a light source module including: a portion exposed through the hole; a substrate including a non-conductive first layer, a second layer laminated on the front surface of the first layer and having a power supply line, and a third layer laminated on the front surface of the second layer; a light-emitting diode on the third layer of the substrate; a pair of power supply pads on the second layer, connected to the power supply line, and electrically connected to the light-emitting diode through a window on the third layer; and a reflection-assisting layer between the pair of power supply pads and having a first portion with a thickness corresponding to the thickness of the second layer and a second portion on a front of the first portion with a thickness corresponding to the thickness of the third layer.

### CROSS-REFERENCE TO RELATED APPLICATIONS

This application is a by-pass continuation application of International Application No. PCT/KR2023/007133, filed on May 25, 2023, which claims priority to Korean Patent Application No. 10-2022-0091347, filed on Jul. 22, 2022, in the Korean Intellectual Property Office, and the disclosures of which are incorporated by reference herein in their entireties.

### BACKGROUND

### 1. Field

The present disclosure relates to a display apparatus and a light source apparatus thereof, and more particular, to a display apparatus including an improved structure to increase a light efficiency of a light-emitting diode and a light source apparatus thereof.

### 2. Description of Related Art

Generally, a display apparatus is a kind of an output apparatus that converts obtained or stored electrical information into visual information and displays the visual information to a user, and the display apparatus is used in various fields, such as home or workplace.

The display apparatus includes a monitor apparatus connected to a personal computer or a server computer, a portable computer device, a navigation terminal device, a general television apparatus, an Internet Protocol television (IPTV), a portable terminal device, such as a smart phone, a tablet PC, a personal digital assistant (PDA) or a cellular phone, various display apparatuses used to reproduce images, such as advertisements or movies in an industrial field, or various kinds of audio/video systems.

The display apparatus includes a light source module to convert electrical information into visual information, and the light source module includes a plurality of light sources configured to independently emit light.

Each of the plurality of light sources includes a light-emitting diode (LED) or an organic light-emitting diode (OLED). For example, the LED or the OLED may be mounted on a circuit board or a substrate.

The substrate may include a pair of power supply pads electrically connected to the LED or the OLED.

### SUMMARY

According to an aspect of the present disclosure, a light source apparatus includes: a reflective sheet comprising a hole formed therein; and a light source module. The light source module includes: a portion exposed through the hole; a substrate including a non-conductive first layer, a second layer laminated on a front surface of the first layer and including a power supply line, and a third layer laminated on a front surface of the second layer; a light-emitting diode on the third layer of the substrate; a pair of power supply pads on the second layer, connected to the power supply line, and electrically connected to the light-emitting diode through a window on the third layer; and a reflection-assisting layer in a space between the pair of power supply pads and including a first portion having a thickness corresponding to a thickness of the second layer and a second portion on a front side of the first portion and having a thickness corresponding to a thickness of the third layer.

A width of the first portion may be less than a width of the second portion.

The second portion may cover a portion of a front surface of the pair of power supply pads.

The width of the first portion may be equal to the width of the second portion.

The reflection-assisting layer may be between the pair of power supply pads and spaced apart from the pair of power supply pads with respect to a width direction.

A gap between the pair of power supply pads may be 100 μm or less.

The window may be between both sides of the second portion of the reflection-assisting layer and the third layer. The pair of power supply pads may be exposed in a forward direction via the window.

The light-emitting diode may include a Distributed Bragg Reflector (DBR) layer.

Light emitted from the light-emitting diode may be reflected by the DBR layer and re-reflected by the reflection-assisting layer.

The third layer may include a White Photo Solder Resist (W-PSR) material.

The reflection-assisting layer may the same material as the third layer and the third layer may be between the pair of power supply pads.

The reflection-assisting layer may contact the front surface of the first layer and may be configured to prevent light emitted from the light-emitting diode from being absorbed by the first layer.

The first layer may be a non-conductive insulation layer, the second layer may be a conductive conduction layer, and the third layer may be a non-conductive protection layer.

The light source apparatus may further include a conductive adhesive material on the window and parallel to the second portion of the reflection-assisting layer, and be configured to electrically connect the pair of power supply pads to the light-emitting diode.

The light-emitting diode may be on a front surface of the substrate and cover the window entirely.

A display apparatus may be capable of increasing a light emission efficiency by forming a reflection-assisting layer in a space between power supply pads, and a light source apparatus thereof.

A beam angle of a light source apparatus may be widened and light efficiency of the light source apparatus may be increased because light emitted from a light-emitting diode including a reflective optical structure is reflected by a reflection-assisting layer.

Further, it may be possible to improve Mura defects because occurrence of bubbles during curing of an optical dome may be minimized by filling a portion of a space formed in a conduction layer and a protection layer with a reflection-assisting layer.

### BRIEF DESCRIPTION OF THE DRAWINGS

The following drawings attached to this specification illustrate embodiments of the present disclosure and help understand the technical idea of the present disclosure along with the description of the invention below. The present disclosure shall not be construed as limited to the matters stated in the drawings.

FIG. 1 illustrates an appearance of a display apparatus according to one or more embodiments.

FIG. 2 illustrates an exploded view of the display apparatus according to one or

more embodiments.

FIG. 3 illustrates a cross-sectional view of a liquid crystal panel of the display apparatus according to one or more embodiments.

FIG. 4 illustrates an exploded view of a light source apparatus according to one or more embodiments.

FIG. 5 illustrates coupling between a light source module and a reflective sheet included in the light source apparatus according to one or more embodiments.

FIG. 6 illustrates a perspective view of a light source included in the light source apparatus according to one or more embodiments.

FIG. 7 illustrates an exploded view of the light source shown in FIG. 6.

FIG. 8 illustrates a cross-section taken along A-A′ direction shown in FIG. 6.

FIG. 9 illustrates a path of light from the light source shown in FIG. 8.

FIG. 10 illustrates a cross-section of a light source according to one or more embodiments of the present disclosure.

### DETAILED DESCRIPTION

In the following description, like reference numerals refer to like elements throughout the specification. Well-known functions or constructions are not described in detail since they would obscure the one or more exemplar embodiments with unnecessary detail. Terms such as “unit”, “module”, “member”, and “block” may be embodied as hardware or software. According to embodiments, a plurality of “unit”, “module”, “member”, and “block” may be implemented as a single component or a single “unit”, “module”, “member”, and “block” may include a plurality of components.

It will be understood that when an element is referred to as being “connected” another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

It will be understood that, although the terms first, second, third, etc., may be used herein to describe various elements, but it should not be limited by these terms. These terms are only used to distinguish one element from another element.

As used herein, the singular forms “a,” “an” and “the” are intended to include the plural forms as well, unless the context clearly indicates otherwise.

An identification code is used for the convenience of the description but is not intended to illustrate the order of each step. The each step may be implemented in the order different from the illustrated order unless the context clearly indicates otherwise.

Reference will now be made in detail to embodiments of the disclosure, examples of which are illustrated in the accompanying drawings.

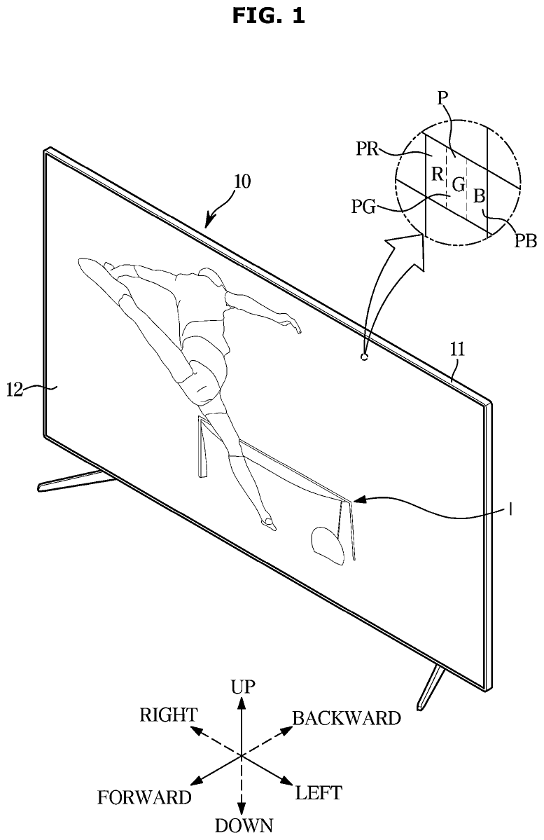

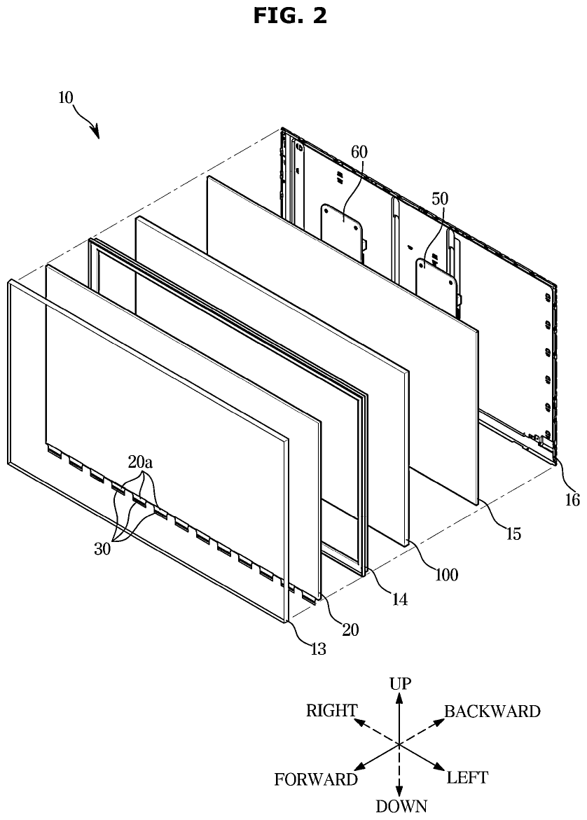

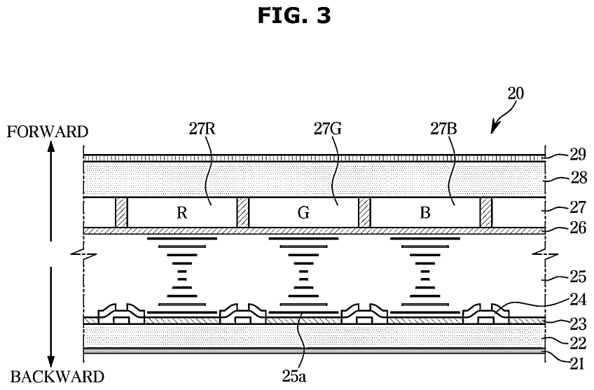

FIG. 1 illustrates an appearance of a display apparatus according to one or more embodiments. FIG. 2 illustrates an exploded view of the display apparatus according to one or more embodiments. FIG. 3 illustrates a cross-sectional view of a liquid crystal panel of the display apparatus according to one or more embodiments.

Referring to FIG. 1, a display apparatus 10 is a device that processes an image signal received from an outside and visually displays the processed image. Hereinafter a case in which the display apparatus 10 is a television is exemplified, but the present disclosure is not limited thereto. For example, the display apparatus 10 may be implemented in various forms, such as a monitor, a portable multimedia device, and a portable communication device, and the display apparatus 10 is not limited in its shape as long as visually displaying an image.

The display apparatus 10 may be a large format display (LFD) installed outdoors, such as a roof of a building or a bus stop. The outdoor is not limited to the outside of a building, and thus the display apparatus 10 according to one or more embodiments may be installed in any places as long as the display apparatus is accessed by a large number of people, even indoors, such as subway stations, shopping malls, movie theaters, companies, and stores.

The display apparatus 10 may receive content data including video data and audio data from various content sources and output video and audio corresponding to the video data and the audio data. For example, the display apparatus 10 may receive content data through a broadcast reception antenna or cable, receive content data from a content playback device, or receive content data from a content providing server of a content provider.

As illustrated in FIG. 1, the display apparatus 10 includes a body 11, a screen 12 provided to display an image I, and a supporter 103 provided below the body 11 to support the body 11.

The body 11 may form an appearance of the display apparatus 10, and a component configured to allow the display apparatus 10 to display the image I and to perform various functions may be provided in the body 11. Although the body 11 shown in FIG. 1 is in the form of a flat plate, the shape of the body 11 is not limited thereto. For example, the body 11 may have a curved plate shape.

The screen 12 may be formed on a front surface of the body 11, and display the image I. For example, the screen 12 may display a still image or a moving image. Further, the screen 12 may display a two-dimensional plane image or a three-dimensional image using binocular parallax of the user.

A plurality of pixels P may be formed on the screen 12 and the image I displayed on the screen 12 may be formed by a combination of the lights emitted from the plurality of pixels P. For example, the image I may be formed on the screen 12 by combining light emitted from the plurality of pixels P as a mosaic.

Each of the plurality of pixels P may emit different brightness and different color of light. In order to emit different brightness of light, each of the plurality of pixels P may include a self-luminous panel (for example, a light-emitting diode panel) configured to directly emit light or a non-self-luminous panel (for example, a liquid crystal panel) configured to transmit or block light emitted by a light source apparatus.

In order to emit light in the various colors, the plurality of pixels P may include sub-pixels PR, PG, and PB, respectively.

The sub-pixels PR, PG, and PB may include a red sub-pixel PR emitting red light, a green sub-pixel PG emitting green light, and a blue sub-pixel PB emitting blue light. For example, the red light may represent a light beam having a wavelength of approximately 620 nm (nanometers, one billionth of a meter) to 750 nm, the green light may represent a light beam having a wavelength of approximately 495 nm to 570 nm, and the blue light may represent a light beam having a wavelength of approximately 450 nm to 495 nm.

By combining the red light of the red sub-pixel PR, the green light of the green sub-pixel PG and the blue light of the blue sub-pixel PB, each of the plurality of pixels P may emit different brightness and different color of light.

As shown in FIG. 2, various components configured to generate the image I on the screen S may be provided inside the body 11.

For example, the body 11 may include a light source apparatus 100 that is a surface light source, a liquid crystal panel 20 configured to block or transmit light emitted from the light source apparatus 100, a control assembly 50 configured to control an operation of the light source apparatus 100 and the liquid crystal panel 20, and a power assembly 60 configured to supply power to the light source apparatus 100 and the liquid crystal panel 20. Further, the body 11 may include a bezel 13, a frame middle mold 14, a bottom chassis 15 and a rear cover 16 which are provided to support and fix the liquid crystal panel 20, the light source apparatus 100, the control assembly 50, and the power assembly 60.

The light source apparatus 100 may include a point light source configured to emit monochromatic light or white light. The light source apparatus 100 may refract, reflect, and scatter light in order to convert light, which is emitted from the point light source, into uniform surface light. For example, the light source apparatus 100 may include a plurality of light sources configured to emit monochromatic light or white light, a diffuser plate configured to diffuse light incident from the plurality of light sources, a reflective sheet configured to reflect light emitted from the plurality of light sources and a rear surface of the diffuser plate, and an optical sheet configured to refract and scatter light emitted from a front surface of the diffuser plate.

As mentioned above, the light source apparatus 100 may refract, reflect, and scatter light emitted from the light source, thereby emitting uniform surface light toward the front side.

Hereinafter a configuration of the light source apparatus 100 will be described in detail.

The liquid crystal panel 20 may be provided in front of the light source apparatus 100 and block or transmit light emitted from the light source apparatus 100 to form the image I.

A front surface of the liquid crystal panel 20 may form the screen S of the display apparatus 10 described above, and the liquid crystal panel 20 may form the plurality of pixels P. In the liquid crystal panel 20, the plurality of pixels P may independently block or transmit light of the light source apparatus 100, and the light transmitted through the plurality of pixels P may form the image I displayed on the screen S.

For example, as shown in FIG. 3, the liquid crystal panel 20 may include a first polarizing film 21, a first transparent substrate 22, a pixel electrode 23, a thin film transistor 24, a liquid crystal layer 25, a common electrode 26, a color filter 27, a second transparent substrate 28, and a second polarizing film 29.

The first transparent substrate 22 and the second transparent substrate 28 may fix and support the pixel electrode 23, the thin film transistor 24, the liquid crystal layer 25, the common electrode 26, and the color filter 27. The first and second transparent substrates 22 and 28 may be formed of tempered glass or transparent resin.

The first polarizing film 21 and the second polarizing film 29 may be provided on the outside of the first and second transparent substrates 22 and 28.

Each of the first polarizing film 21 and the second polarizing film 29 may transmit a specific light beam and block other light beams. For example, the first polarizing film 21 may transmit a light beam having a magnetic field vibrating in a first direction and block other light beams. In addition, the second polarizing film 29 may transmit a light beam having a magnetic field vibrating in a second direction and block other light beams. In this case, the first direction and the second direction may be perpendicular to each other. Accordingly, a polarization direction of the light transmitted through the first polarizing film 21 and a vibration direction of the light transmitted through the second polarizing film 29 may be perpendicular to each other. As a result, in general, light may not pass through the first polarizing film 21 and the second polarizing film 29 at the same time.

The color filter 27 may be provided on an inner side of the second transparent substrate 28.

The color filter 27 may include a red filter 27R transmitting red light, a green filter 27G transmitting green light, and a blue filter 27B transmitting blue light. The red filter 27R, the green filter 27G, and the blue filter 27B may be disposed parallel to each other. A region, in which the color filter 27 is formed, may correspond to the pixel P described above. A region, in which the red filter 27R is formed, may correspond to the red sub-pixel PR, a region, in which the green filter 27G is formed, may correspond to the green sub-pixel PG, and a region, in which the blue filter 27B is formed, may correspond to the blue sub-pixel PB.

The pixel electrode 23 may be provided on an inner side of the first transparent substrate 22, and the common electrode 26 may be provided on an inner side of the second transparent substrate 28.

The pixel electrode 23 and the common electrode 26 may be formed of a metal material through which electricity is conducted, and the pixel electrode 23 and the common electrode 26 may generate an electric field to change the arrangement of liquid crystal molecules 25a forming the liquid crystal layer 25 to be described below.

The pixel electrode 23 and the common electrode 26 may be formed of a transparent material, and may transmit light incident from the outside. For example, the pixel electrode 23 and the common electrode 26 may include indium tin oxide (ITO), indium zinc oxide (IZO), silver nanowire (Ag nano wire), carbon nanotube (CNT), graphene, or poly (3,4-ethylenedioxythiophene) (PEDOT).

The thin film transistor (TFT) 24 may be provided in an inner side of the second transparent substrate 22.

The TFT 24 may transmit or block a current flowing through the pixel electrode 23. For example, an electric field may be formed or removed between the pixel electrode 23 and the common electrode 26 in response to turning on (closing) or turning off (opening) the TFT 24.

The TFT 24 may be formed of poly-silicon, and may be formed by semiconductor processes, such as lithography, deposition, and ion implantation.

The liquid crystal layer 25 may be formed between the pixel electrode 23 and the common electrode 26, and the liquid crystal layer 25 may be filled with the liquid crystal molecules 25a.

Liquid crystals represent an intermediate state between a solid (crystal) and a liquid. Most of the liquid crystal materials are organic compounds, and the molecular shape is in the shape of an elongated rod, and the orientation of molecules is in an irregular state in one direction, but in a regular state in other directions. As a result, the liquid crystal has both the fluidity of the liquid and the optical anisotropy of the crystal (solid).

In addition, liquid crystals also exhibit optical properties according to changes in an electric field. For example, in the liquid crystal, the orientation of molecules forming the liquid crystal may change according to a change in an electric field. In response to an electric field being generated in the liquid crystal layer 25, the liquid crystal molecules 25a of the liquid crystal layer 25 may be disposed along the direction of the electric field. In response to the electric field not being generated in the liquid crystal layer 25, the liquid crystal molecules 25a may be disposed irregularly or disposed along an alignment layer (not shown). As a result, the optical properties of the liquid crystal layer 25 may vary depending on the presence or absence of the electric field passing through the liquid crystal layer 25.

A cable 20a configured to transmit image data to the liquid crystal panel 20, and a display driver integrated circuit (DDI) (hereinafter referred to as ‘driver IC’) 30 configured to process digital image data and output an analog image signal may be provided at one side of the liquid crystal panel 20.

The cable 20a may electrically connect the control assembly 50/the power assembly 60 to the driver IC 30, and may also electrically connect the driver IC 30 to the liquid crystal panel 20. The cable 20a may include a flexible flat cable or a film cable that is bendable.

The driver IC 30 may receive image data and power from the control assembly 50/the power assembly 60 through the cable 20a. The driver IC 30 may transmit the image data and driving current to the liquid crystal panel 20 through the cable 20a.

In addition, the cable 20a and the driver IC 30 may be integrally implemented as a film cable, a chip on film (COF), or a tape carrier package (TCP). In other words, the driver IC 30 may be arranged on the cable 20a. However, the disclosure is not limited thereto, and the driver IC 30 may be arranged on the liquid crystal panel 20.

The control assembly 50 may include a control circuit configured to control an operation of the liquid crystal panel 20 and the light source apparatus 100. The control circuit may process image data received from an external content source, transmit the image data to the liquid crystal panel 20, and transmit dimming data to the light source apparatus 100.

The power assembly 60 may supply power to the liquid crystal panel 20 and the light source apparatus 100 to allow the light source apparatus 100 to output surface light and to allow the liquid crystal panel 20 to block or transmit the light of the light source apparatus 100.

The control assembly 50 and the power assembly 60 may be implemented as a printed circuit board and various circuits mounted on the printed circuit board. For example, the power circuit may include a capacitor, a coil, a resistance element, a processor, and a power circuit board on which the capacitor, the coil, the resistance element, and the processor are mounted. Further, the control circuit may include a memory, a processor, and a control circuit board on which the memory and the processor are mounted.

Hereinafter the light source apparatus 100 will be described.

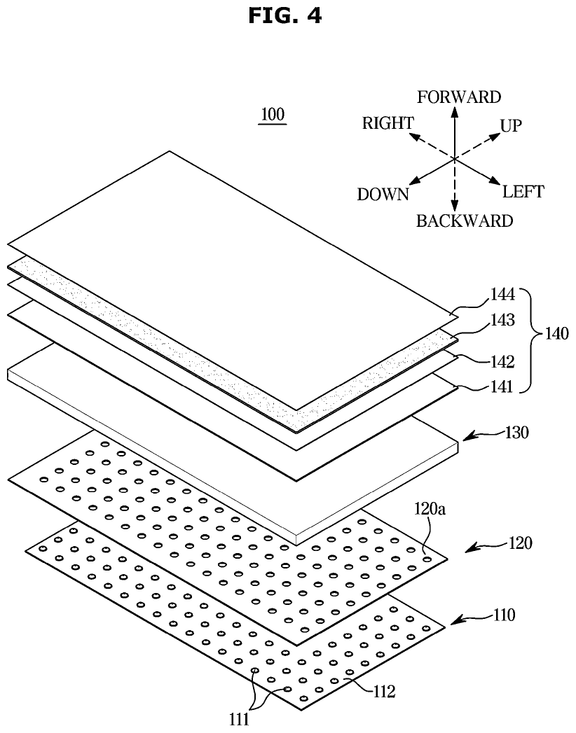

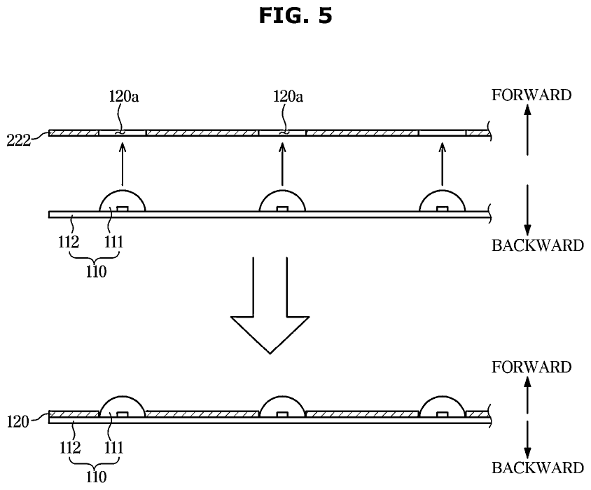

FIG. 4 illustrates an exploded view of a light source apparatus according to one or more embodiments. FIG. 5 illustrates coupling between a light source module and a reflective sheet included in the light source apparatus according to one or more embodiments.

The light source apparatus 100 may include a light source module 110 configured to generate light, a reflective sheet 120 configured to reflect light, a diffuser plate 130 configured to uniformly diffuse light, and an optical sheet 140 configured to improve a luminance of light that is emitted.

The light source module 110 may include a plurality of light sources 111 configured to emit light, and a substrate 112 provided to support/fix the plurality of light sources 111.

The plurality of light sources 111 may be disposed in a predetermined pattern to emit light with the uniform luminance. The plurality of light sources 111 may be disposed in such a way that a distance between one light source and light sources adjacent thereto is the same.

For example, as shown in FIG. 4, the plurality of light sources 111 may be disposed in rows and columns. Accordingly, the plurality of light sources may be disposed such that an approximately square is formed by four adjacent light sources. In addition, any one light source may be disposed adjacent to four light sources, and a distance between one light source and four adjacent light sources may be approximately the same.

Alternatively, the plurality of light sources may be disposed in a plurality of rows, and a light source belonging to each row may be disposed at the center of two light sources belonging to an adjacent row. Accordingly, the plurality of light sources may be disposed such that an approximately equilateral triangle is formed by three adjacent light sources. In this case, one light source may be disposed adjacent to six light sources, and a distance between one light source and six adjacent light sources may be approximately the same.

However, the pattern in which the plurality of light sources 111 is disposed is not limited to the pattern described above, and the plurality of light sources 111 may be disposed in various patterns to emit light with the uniform luminance.

The light source 111 may employ an element configured to emit monochromatic light (light of a specific wavelength, for example, blue light) or white light (for example, light of a mixture of red light, green light, and blue light) in various directions by receiving power. For example, the light source 111 may include a light-emitting diode (LED).

The substrate 112 may fix the plurality of light sources 111 to prevent a change in the position of the light source 111. Further, the substrate 112 may supply power, which is for the light source 111 to emit light, to the light source 111.

The substrate 112 may fix the plurality of light sources 111 and may be configured with synthetic resin or tempered glass or a printed circuit board (PCB) on which a conductive power supply line for supplying power to the light source 111 is formed.

The reflective sheet 120 may reflect light emitted from the plurality of light sources 111 to the front side or in a direction close to the front side.

In the reflective sheet 120, a plurality of through holes 120a is formed at positions corresponding to each of the plurality of light sources 111 of the light source module 110. In addition, the light source 111 of the light source module 110 may pass through the through hole 120a and protrude to the front of the reflective sheet 120.

For example, as shown in the upper portion of FIG. 5, in the process of assembling the reflective sheet 120 and the light source module 110, the plurality of light sources 111 of the light source module 110 is inserted into the through holes 120a formed on the reflective sheet 120. Accordingly, as shown in the lower portion of FIG. 5, the substrate 112 of the light source module 110 may be disposed behind the reflective sheet 120, but the plurality of light sources 111 of the light source module 110 may be disposed in front of the reflective sheet 120.

Accordingly, the plurality of light sources 111 may emit light in front of the reflective sheet 120.

The plurality of light sources 111 may emit light in various directions in front of the reflective sheet 120. The light may be emitted not only toward the diffuser plate 130 from the light source 111, but also toward the reflective sheet 120 from the light source 111. The reflective sheet 120 may reflect light, which is emitted toward the reflective sheet 120, toward the diffuser plate 130.

Light emitted from the light source 111 may pass through various objects, such as the diffuser plate 130 and the optical sheet 140. Among incident light beams passing through the diffuser plate 130 and the optical sheet 140, some of the incident light beams may be reflected from the surfaces of the diffuser plate 130 and the optical sheet 140. The reflective sheet 120 may reflect light reflected by the diffuser plate 130 and the optical sheet 140.

The diffuser plate 130 may be provided in front of the light source module 110 and the reflective sheet 120, and may evenly distribute the light emitted from the light source 111 of the light source module 110.

As described above, the plurality of light sources 111 may be disposed in various places on the rear surface of the light source apparatus 100. Although the plurality of light sources 111 is disposed at equal intervals on the rear surface of the light source apparatus 100, unevenness in luminance may occur depending on the positions of the plurality of light sources 111.

Within the diffuser plate 130, the diffuser plate 130 may diffuse light emitted from the plurality of light sources 111 to remove unevenness in luminance caused by the plurality of light sources 111. In other words, the diffuser plate 130 may uniformly emit uneven light of the plurality of light sources 111 to the front surface.

The optical sheet 140 may include various sheets for improving luminance and luminance uniformity. For example, the optical sheet 140 may include a diffusion sheet 141, a first prism sheet 142, a second prism sheet 143, and a reflective polarizing sheet 144.

The diffusion sheet 141 may diffuse light for the luminance uniformity. The light emitted from the light source 111 may be diffused by the diffuser plate 130 and may be diffused again by the diffusion sheet 141 included in the optical sheet 140.

The first and second prism sheets 142 and 143 may increase the luminance by condensing light diffused by the diffusion sheet 141. The first and second prism sheets 142 and 143 may include a prism pattern in the shape of a triangular prism, and the prism pattern, which is provided in plurality, may be disposed adjacent to each other to form a plurality of strips.

The reflective polarizing sheet 144 is a type of polarizing film and may transmit some of the incident light beams and reflect others for improving the luminance. For example, the reflective polarizing sheet 144 may transmit polarized light in the same direction as a predetermined polarization direction of the reflective polarizing sheet 144, and may reflect polarized light in a direction different from the polarization direction of the reflective polarizing sheet 144. In addition, the light reflected by the reflective polarizing sheet 144 is recycled inside the light source apparatus 100, and thus the luminance of the display apparatus 10 may be improved by the light recycling.

The optical sheet 140 is not limited to the sheet or film shown in FIG. 4, and may include more various sheets, such as a protective sheet, or films.

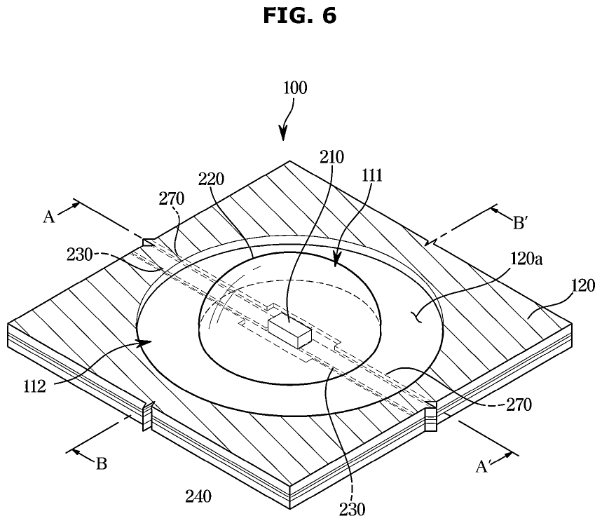

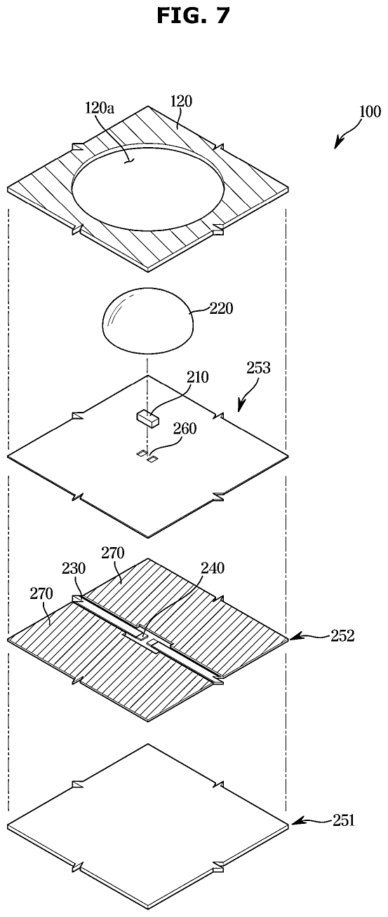

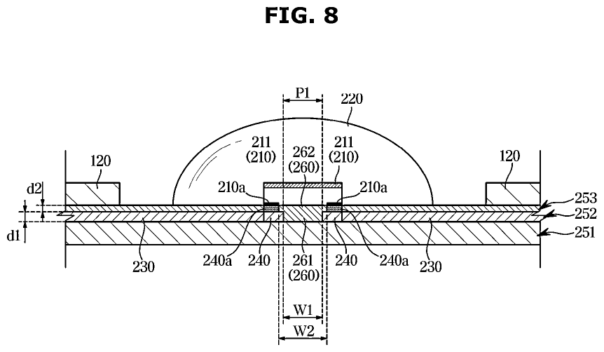

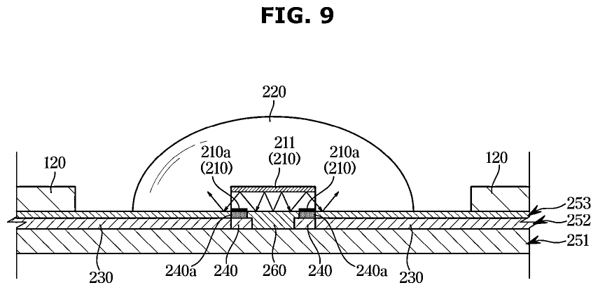

FIG. 6 illustrates a perspective view of a light source included in the light source apparatus according to one or more embodiments. FIG. 7 illustrates an exploded view of the light source shown in FIG. 6. FIG. 8 illustrates a cross-section taken along A-A′ direction shown in FIG. 6. FIG. 9 illustrates a path of light from the light source shown in FIG. 8.

The light source 111 of the light source apparatus 100 will be described with reference to FIGS. 6 to 8.

As described above, the light source module 110 may include the plurality of light sources 111. The plurality of light sources 111 may protrude forward of the reflective sheet 120 from the rear of the reflective sheet 120 by passing through the through hole 120a. Accordingly, as shown in FIGS. 6 and 7, the light source 111 and a part of the substrate 112 may be exposed toward the front of the reflective sheet 120 through the through hole 120a.

The light source 111 may include an electrical/mechanical structure disposed in a region defined by the through hole 120a of the reflective sheet 120.

Each of the plurality of light sources 111 may include a light-emitting diode 210, and an optical dome 220.

In order to improve the uniformity of the surface light emitted by the light source apparatus 100 and to improve the contrast ratio by local dimming, the number of light sources 111 may be increased. As a result, a region occupied by each of the plurality of light sources 111 may be narrowed.

The light-emitting diode 210 may include a P-type semiconductor and an N-type semiconductor for emitting light by recombination of holes and electrons. In addition, the light-emitting diode 210 may be provided with a pair of electrodes 210a for supplying holes and electrons to the P-type semiconductor and the N-type semiconductor, respectively.

The light-emitting diode 210 may convert electrical energy into optical energy. In other words, the light-emitting diode 210 may emit light having a maximum intensity at a predetermined wavelength to which power is supplied. For example, the light-emitting diode 210 may emit blue light having a peak value at a wavelength indicating blue color (for example, a wavelength between 450 nm and 495 nm).

The light-emitting diode 210 may be directly attached to the substrate 112 in a Chip On Board (COB) method. In other words, the light source 111 may include the light-emitting diode 210 in which a light-emitting diode chip or a light-emitting diode die is directly attached to the substrate 112 without an additional packaging.

To reduce the region occupied by the light-emitting diode 210, the light-emitting diode 210 may be manufactured as a flip-chip type that does not include a Zener diode. As for the flip-chip type light-emitting diode 210, when the light-emitting diode corresponding to a semiconductor element is attached to the substrate 112, an electrode pattern of the semiconductor element may be directly fused to the substrate 112 without using an intermediate medium such as a metal lead (wire) or a ball grid array (BGA).

Accordingly, it is possible to miniaturize the light source 111 including the flip-chip type light-emitting diode 210 because the metal lead (wire) or ball grid array is omitted.

In order to miniaturize the light source 111, the light source module 110, in which the flip-chip type light-emitting diode 210 is attached to the substrate 112 in a chip-on-board method, may be manufactured.

On the substrate 112, a power supply line 230 and a power supply pad 240 for supplying power to the flip-chip type light-emitting diode 210 are provided.

On the substrate 112, the power supply line 230 for supplying electrical signals and/or power to the light-emitting diode 210 from the control assembly 50 and/or the power assembly 60 is provided.

As shown in FIG. 8, the substrate 112 may be formed by alternately laminating an insulation layer 251 that is non-conductive and a conduction layer 252 that is conductive.

A line or pattern, through which power and/or electrical signals pass, may be formed on the conduction layer 252. The conduction layer 252 may be formed of various materials having an electrical conductivity. For example, the conduction layer 252 may be formed of various metal materials, such as copper (Cu), tin (Sn), aluminum (Al), or an alloy thereof.

A dielectric of the insulation layer 251 may insulate between lines or patterns of the conduction layer 252. The insulation layer 251 may be formed of a dielectric for electrical insulation, such as FR-4.

The power supply line 230 may be implemented by a line or pattern formed on the conduction layer 252.

The power supply line 230 may be electrically connected to the light-emitting diode 210 through the power supply pad 240.

The power supply pad 240 may be formed in such a way that the power supply line 230 is exposed to the outside.

A protection layer 253 configured to prevent or suppress damages caused by an external impact and/or damages caused by a chemical action (for example, corrosion, etc.) and/or damages caused by an optical action, to the substrate 112 may be formed at an outermost part of the substrate 112. The protection layer 253 may include a photo solder resist (PSR).

As shown in FIG. 8, the protection layer 253 may cover the power supply line 230 to prevent the power supply line 230 from being exposed to the outside.

For electrical contact between the power supply line 230 and the light-emitting diode 210, a window may be formed in the protection layer 253 to expose a portion of the power supply line 230 to the outside. A portion of the power supply line 230 exposed to the outside through the window of the protection layer 253 may form the power supply pad 240.

A conductive adhesive material 240a for the electrical contact between the power supply line 230 exposed to the outside and the electrode 210a of the light-emitting diode 210 may be applied to the power supply pad 240. The conductive adhesive material 240a may be applied within the window of the protection layer 253.

The electrode 210a of the light-emitting diode 210 may be in contact with the conductive adhesive material 240a, and the light-emitting diode 210 may be electrically connected to the power supply line 230 through the conductive adhesive material 240a.

The conductive adhesive material 240a may include a solder having an electrical conductivity. However, the present disclosure is not limited thereto, and the conductive adhesive material 240a may include electrically conductive epoxy adhesives.

Power may be supplied to the light-emitting diode 210 through the power supply line 230 and the power supply pad 240, and in response to the supply of the power, the light-emitting diode 210 may emit light. A pair of power supply pads 240 corresponding to each of the pair of electrodes 210a provided in the flip-chip type light-emitting diode 210 may be provided.

The optical dome 220 may cover the light-emitting diode 210. The optical dome 220 may prevent or suppress damages to the light-emitting diode 210 caused by an external mechanical action and/or damage to the light-emitting diode 210 caused by a chemical action.

The optical dome 220 may have a dome shape formed in such a way that a sphere is cut into a surface not including the center thereof, or may have a hemispherical shape in such a way that a sphere is cut into a surface including the center thereof. A vertical cross section of the optical dome 220 may be a bow shape or a semicircle shape.

The optical dome 220 may be formed of silicone or epoxy resin. For example, the molten silicon or epoxy resin may be discharged onto the light-emitting diode 210 through a nozzle, and the discharged silicon or epoxy resin may be cured, thereby forming the optical dome 220.

Accordingly, the shape of the optical dome 220 may vary depending on the viscosity of the liquid silicone or epoxy resin. For example, in a state in which the optical dome 220 is manufactured using silicon having a thixotropic index of about 2.7 to 3.3 (appropriately, 3.0), the optical dome 220 may have a dome ratio, indicating a ratio of a height of a dome to a diameter of a base of the dome (a height of the dome/a diameter of a base), of approximately 2.5 to 3.1 (appropriately 2.8). For example, the optical dome 220 formed of silicon having a thixotropic index of approximately 2.7 to 3.3 (appropriately, 3.0) may have a diameter of the base of approximately 2.5 mm and a height of approximately 0.7 mm.

The optical dome 220 may be optically transparent or translucent. Light emitted from the light-emitting diode 210 may be emitted to the outside by passing through the optical dome 220.

In this case, the dome-shaped optical dome 220 may refract light like a lens. For example, light emitted from the light-emitting diode 210 may be refracted by the optical dome 220 and thus may be dispersed.

As mentioned above, the optical dome 220 may disperse light emitted from the light-emitting diode 210 as well as protecting the light-emitting diode 210 from external mechanical and/or chemical or electrical actions.

Although not shown, a dissipative member is formed near the optical dome 220 to protect the light-emitting diode 210 from electrostatic discharge. The dissipative member may absorb an electric shock caused by electrostatic discharge generated near the optical dome 220.

Referring to FIG. 8, the light source module 110 may include the insulation layer 251 that is non-conductive, the conduction layer 252 laminated on a front surface of the insulation layer 251 and including the power supply line 230, and the protection layer 253 that is non-conductive and laminated on the front surface of the conduction layer 252. The insulation layer 251 may be referred to as a first layer, the conduction layer 252 as a second layer, and the protection layer 253 as a third layer, respectively.

The light-emitting diode 210 may be disposed on the protection layer 253. More particularly, the light-emitting diode 210 may be disposed on the front surface of the substrate 112 to cover the window formed on the protection layer 253.

The pair of power supply pads 240 may be formed on the conduction layer 252 and connected to the power supply line 230. The pair of power supply pads 240 may be electrically connected to the light-emitting diode 210 through the window formed on the protection layer 253. The pair of power supply pads 240 may be arranged to be separated from each other.

The light source module 110 may include a reflection-assisting layer 260.

The reflection-assisting layer 260 may include a first portion 261 and a second portion 262.

The first portion 261 may be disposed in a space between the pair of power supply pads 240. The first portion 261 may have a thickness corresponding to a thickness of the conduction layer 252. Particularly, a length of the first portion 261 extending along the front and rear direction (i.e. the forward and backward direction, respectively) may be provided to be equal to the thickness d1 of the conduction layer 252.

The second portion 262 may be disposed on the front side of the first portion 261. The second portion 262 may be formed of the same material as the first portion 261 and may be formed together with the first portion 261. The reflection-assisting layer 260 may include a White Photo Solder Resist (W-PSR) material having a high reflectance.

The second portion 262 may have a thickness corresponding to a thickness of the protection layer 253. Particularly, a length of the second portion 262 extending along the front and rear direction (i.e. the forward and backward direction) may be provided to be equal to the thickness d2 of the protection layer 253.

A width W1 of the first portion 261 of the reflection-assisting layer 260 may be provided to be less than a width W2 of the second portion 262. Particularly, a length in which the first portion 261 of the reflection-assisting layer 260 extends in the left and right direction may be less than a length in which the second portion 262 of the reflection-assisting layer 260 extends in the left and right direction.

The second portion 262 of the reflection-assisting layer 260 may be formed to cover a portion of the front surface of the pair of power supply pads 240. In other words, the second portion 262 of the reflection-assisting layer 260 may be positioned to cover a portion of the pair of power supply pads 240 in front of the pair of power supply pads 240 that are separated from each other.

For example, the reflective auxiliary layer 260 may be filled in the space between the pair of power supply pads 240 and arranged to cover a portion of the front surface of the pair of power supply pads 240 to form a pair of windows of the protection layer 253 on both sides.

Areas in which the second portion 262 of the reflection-assisting layer 260 shown in FIGS. 8 and 9 covers the front surface of the pair of power supply pads 240 are approximately same. However, the areas of the second portion 262 covering the front surface of the pair of power supply pads 240 may not be limited thereto. For example, an area of the second portion 262 of the reflection-assisting layer 260 covering the front surface of the power supply pad 240 on one side and an area of the second portion 262 covering the front surface of the power supply pad 240 on the other side may be different from each other.

In a process of forming the protection layer 253 on the front surface of the conduction layer 252, the protection layer 253 may be biased toward one side or the other side of the power supply pad 240.

When the reflection-assisting layer 260 is not formed between the pair of power supply pads 240 and an empty space is left, areas of the pair of power supply pads 240 exposed in front of the protection layer 253 may be formed differently.

Therefore, because the reflection-assisting layer 260 together with the protection layer 253 are formed between the pair of power supply pads 240 according to the present disclosure, it is possible to reduce a defect rate due to size asymmetry of the pair of power supply pads 240.

Further, the conductive adhesive material 240a may be applied on the window of the protection layer 253 so as to be arranged parallel to the second portion 262 of the reflection-assisting layer 260 to electrically connect the pair of power supply pads 240 and the light-emitting diode 210.

The reflection-assisting layer 260 may be formed to be in contact with the front surface of the insulation layer 251. Particularly, the first portion 261 of the reflection-assisting layer 260 may be disposed to be in contact with the front surface of the insulation layer 251.

Therefore, the reflection-assisting layer 260 may cover the front side of the insulation layer 251 to prevent a case in which the insulation layer 251 faces the light-emitting diode 210 through the space between the pair of power supply pads 240.

Accordingly, it is possible to minimize light loss caused by light emitted from the lower portion of the light-emitting diode 210 being absorbed by the insulation layer 251.

A gap P1 between the pair of power supply pads 240 may be provided to be 100 μm or less. It is appropriate that the gap P1 between the pair of power supply pads 240 is provided to be approximately 93 um.

The light-emitting diode 210 may include a Distributed Bragg Reflector (DBR) layer 211.

The DBR layer 211 is a multilayer reflector composed of two materials having different refractive indices. Fresnel reflection occurs at an interface of each DBR layer 211 due to the difference in refractive indices of each material. Accordingly, light incident on the DBR layer may be reflected at a wide range of angles and thus a beam angle of the light-emitting diode 210 may be provided to be approximately 165 degrees or more.

As illustrated in FIG. 9, light emitted from the light-emitting diode 210 may be reflected by the DBR layer 211 and re-reflected by the reflection-assisting layer 260. Accordingly, it is possible to prevent loss of light traveling into the space between the pair of power supply pads 240.

Particularly, because the reflection-assisting layer 260 is formed of a material having a higher reflectance than the insulation layer 251, the reflection-assisting layer 260 may cover the front side of the insulation layer 251, thereby minimizing light loss caused by light traveling toward the rear of the light-emitting diode 210 being absorbed by the insulation layer 251.

Hereinafter a process of forming the light source apparatus 100 according to one or more embodiments of the present disclosure will be described.

The substrate 112 may be formed by laminating the conduction layer 252 on the insulation layer 251 that is non-conductive. The power supply line 230 may be formed on the conduction layer 252 to supply an electrical signal to the light-emitting diode 210, and the power supply pad 240 electrically connected to the light-emitting diode 210 from an end portion of the power supply line 230 may be formed.

The protection layer 253 may be formed on the front side of the conduction layer 252. The protection layer 253 may include a White Photo Solder Resist (W-PSR) material. Therefore, the protection layer 253 may be formed through an exposure and development process. In the development process, only a portion, which receives light, may remain and thus the protection layer 253 may be finally formed. Therefore, the protection layer 253 may cover the front side of the conduction layer 252 to protect the conduction layer 252.

The reflection-assisting layer 260 may be formed together with the protection layer 253. The reflection-assisting layer 260 is also formed of the same material as the protection layer 253, such as W-PSR, and may undergo the same exposure and development process as the protection layer 253. For example, the reflection-assisting layer 260 may be formed simultaneously with the protection layer 253 and then filled between the pair of power supply pads 240.

Therefore, according to the present disclosure, the reflection-assisting layer 260 may be formed by exposing a portion of the protection layer 253 corresponding to a space between the pair of power supply pads 240 without covering the portion with a mask.

At the same time, a portion corresponding to the window of the protection layer 253 is covered with a mask so as not to be exposed to light, and thus the pair of power supply pads 240 may be exposed to the front of the substrate 112. Accordingly, a structure, in which the pair of power supply pads 240 and the light-emitting diode 210 are electrically connected, may be implemented.

Therefore, as the window of the protection layer 253 is formed between both sides of the second portion 262 of the reflection-assisting layer 260 and the protection layer 253, the pair of power supply pads 240 may be exposed forward. The front of the exposed power supply pads 240 may be filled with the conductive adhesive material 240a.

According to the present disclosure, the large number of light-emitting diodes 210 may be mounted relative to the size of the substrate 112. Accordingly, the gap P1 between the pair of separate power supply pads 240 electrically connected to the electrode 210a of the light-emitting diode 210 may be formed to be less than 100 um.

However, it is usually difficult to form the protection layer 253 with a volume corresponding to such a small space in a one-to-one manner due to process difficulties, and thus the corresponding portion is left as an empty space.

However, according to the present disclosure, because the light-emitting diode 210 includes the DBR layer 211, a ratio of light that is diffusely reflected toward the lower portion of the light-emitting diode 210 is high. Therefore, there is a technical motivation to form the reflection-assisting layer 260 between the pair of power supply pads 240 together with the protection layer 253. In addition, it is possible to stably form the reflection-assisting layer 260 in the process by forming the reflection-assisting layer 260 to cover a portion of the front surface of the pair of power supply pads 240 while seeking to improve the luminance and Mura defects through the reflection-assisting layer 260.

Table 1 shows the luminance and luminance increase rate in a case in which the reflection-assisting layer 260 is not provided in the space between the pair of power supply pads 240, in a case in which the reflection-assisting layer 260 is provided with a high gloss particle size, and in a case in which the reflection-assisting layer 260 is provided with a low gloss particle size.

TABLE 1

| | | Luminance Increase |
|---|---|---|
| Classification | Luminance (nit) | Rate (%) |
| Reflection-assisting layer X | 12529 | 100.00 |
| High Gloss Reflection- | 12994 | 103.70 |
| assisting layer O | | |
| Low Gloss Reflection- | 13011 | 103.80 |
| assisting layer O | | |

As shown in the Table 1, when the reflection-assisting layer 260 is formed in the space between the windows of the protection layer 253 and the space between the pair of power supply pads 240, light reflected directly below the light-emitting diode 210 is re-reflected by the reflection-assisting layer 260, thereby showing a luminance increase rate of approximately 3% compared to the luminance in the case in which the reflection-assisting layer 260 is not formed. Therefore, in the present disclosure, the luminance and Mura defects of the display apparatus may be improved by forming the reflection-assisting layer 260 in the empty space between the pair of power supply pads 240 and the conductive adhesive material 240a applied to the front surface of the pair of power supply pads 240.

Further, by forming the reflection-assisting layer 260 between the pair of power supply pads 240 at the same time as forming the protection layer 253, it is possible to reduce occurrence of a defect in which the sizes of the pair of power supply pads 240 exposed forward through the window of the protection layer 253 are formed asymmetrically.

In addition, when heat is applied to harden the optical dome 220, bubbles trapped in the empty space between the pair of power supply pads 240 may grow larger and cause Mura defects of the light source module 110 and the display apparatus 10. Therefore, according to the present disclosure, the space between the pair of power supply pads 240 and the space between the windows of the protection layer 253 may be filled with the reflection-assisting layer 260 to prevent the generation of bubbles. Accordingly, it is possible to contribute to the improvement of the overall Mura defects of the display apparatus 10 and the light source apparatus 100.

In addition, the light-emitting diode 210 may be disposed on the front surface of the substrate 112 so as to cover the entire open window of the protection layer 253. Accordingly, light traveling outward from the light-emitting diode 210 may be effectively reflected by the protection layer 253 without being absorbed by the conductive adhesive material 240a or the power supply pad 240, thereby improving the overall luminance and Mura defects.

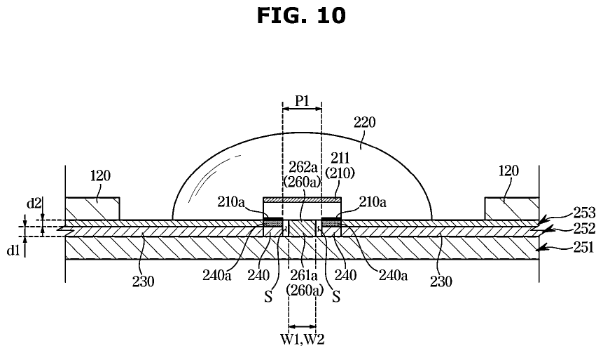

FIG. 10 illustrates a cross-section of a light source according to one or more embodiments of the present disclosure.

Referring to FIG. 10, a light source module 110 may include a plurality of light sources 111, as described above. The plurality of light sources 111 may protrude forward of a reflective sheet 120 from the rear of the reflective sheet 120 by passing through a through hole 120a. Accordingly, the light source 111 and a part of a substrate 112 may be exposed toward the front of the reflective sheet 120 through the through hole 120a.

The light source 111 may include an electrical/mechanical structure disposed in a region defined by the through hole 120a of the reflective sheet 120.

Each of the plurality of light sources 111 may include a light-emitting diode 210 and an optical dome 220.

In order to improve the uniformity of the surface light emitted by the light source apparatus 100 and to improve the contrast ratio by local dimming, the number of light sources 111 may be increased. As a result, a region occupied by each of the plurality of light sources 111 may be narrowed.

The light-emitting diode 210 may include a P-type semiconductor and an N-type semiconductor for emitting light by recombination of holes and electrons. In addition, the light-emitting diode 210 may be provided with a pair of electrodes 210a for supplying holes and electrons to the P-type semiconductor and the N-type semiconductor, respectively.

The light-emitting diode 210 may be directly attached to the substrate 112 in a Chip On Board (COB) method. In other words, the light source 111 may include the light-emitting diode 210 in which a light-emitting diode chip or a light-emitting diode die is directly attached to the substrate 112 without an additional packaging.

To reduce the region occupied by the light-emitting diode 210, the light-emitting diode 210 may be manufactured as a flip-chip type that does not include a Zener diode. As for the flip-chip type light-emitting diode 210, when the light-emitting diode corresponding to a semiconductor element is attached to the substrate 112, an electrode pattern of the semiconductor element may be directly fused to the substrate 112 without using an intermediate medium such as a metal lead (wire) or a ball grid array (BGA).

Accordingly, it is possible to miniaturize the light source 111 including the flip-chip type light-emitting diode 210 because the metal lead (wire) or ball grid array is omitted.

In order to miniaturize the light source 111, the light source module 110, in which the flip-chip type light-emitting diode 210 is attached to the substrate 112 in a chip-on-board method, may be manufactured.

On the substrate 112, a power supply line 230 and a power supply pad 240 for supplying power to the flip-chip type light-emitting diode 210 are provided.

On the substrate 112, the power supply line 230 for supplying electrical signals and/or power to the light-emitting diode 210 from a control assembly 50 and/or a power assembly 60 is provided.

As shown in FIG. 10, the substrate 112 may be formed by alternately laminating an insulation layer 251 that is non-conductive and a conduction layer 252 that is conductive.

A line or pattern, through which power and/or electrical signals pass, may be formed on the conduction layer 252. The conduction layer 252 may be formed of various materials having an electrical conductivity. For example, the conduction layer 252 may be formed of various metal materials, such as copper (Cu), tin (Sn), aluminum (Al), or an alloy thereof.

A dielectric of the insulation layer 251 may insulate between lines or patterns of the conduction layer 252. The insulation layer 251 may be formed of a dielectric for electrical insulation, such as FR-4.

The power supply line 230 may be implemented by a line or pattern formed on the conduction layer 252.

The power supply line 230 may be electrically connected to the light-emitting diode 210 through the power supply pad 240.

The power supply pad 240 may be formed in such a way that the power supply line 230 is exposed to the outside.

A protection layer 253 configured to prevent or suppress damages caused by an external impact and/or damages caused by a chemical action (for example, corrosion, etc.) and/or damages caused by an optical action, to the substrate 112 may be formed at an outermost part of the substrate 112. The protection layer 253 may include a photo solder resist (PSR).

As shown in FIG. 10, the protection layer 253 may cover the power supply line 230 to prevent the power supply line 230 from being exposed to the outside.

For electrical contact between the power supply line 230 and the light-emitting diode 210, a window may be formed in the protection layer 253 to expose a portion of the power supply line 230 to the outside. A portion of the power supply line 230 exposed to the outside through the window of the protection layer 253 may form the power supply pad 240.

A conductive adhesive material 240a for the electrical contact between the power supply line 230 exposed to the outside and the electrode 210a of the light-emitting diode 210 may be applied to the power supply pad 240. The conductive adhesive material 240a may be applied within the window of the protection layer 253.

The electrode 210a of the light-emitting diode 210 may be in contact with the conductive adhesive material 240a, and the light-emitting diode 210 may be electrically connected to the power supply line 230 through the conductive adhesive material 240a.

The conductive adhesive material 240a may include a solder having an electrical conductivity. However, the present disclosure is not limited thereto, and the conductive adhesive material 240a may include electrically conductive epoxy adhesives.

Power may be supplied to the light-emitting diode 210 through the power supply line 230 and the power supply pad 240, and in response to the supply of the power, the light-emitting diode 210 may emit light. A pair of power supply pads 240 corresponding to each of the pair of electrodes 210a provided in the flip-chip type light-emitting diode 210 may be provided.

The optical dome 220 may cover the light-emitting diode 210. The optical dome 220 may prevent or suppress damages to the light-emitting diode 210 caused by an external mechanical action and/or damage to the light-emitting diode 210 caused by a chemical action.

The optical dome 220 may have a dome shape formed in such a way that a sphere is cut into a surface not including the center thereof, or may have a hemispherical shape in such a way that a sphere is cut into a surface including the center thereof. A vertical cross section of the optical dome 220 may be a bow shape or a semicircle shape.

The optical dome 220 may be formed of silicone or epoxy resin. For example, the molten silicon or epoxy resin may be discharged onto the light-emitting diode 210 through a nozzle, and the discharged silicon or epoxy resin may be cured, thereby forming the optical dome 220.

Accordingly, the shape of the optical dome 220 may vary depending on the viscosity of the liquid silicone or epoxy resin. For example, in a state in which the optical dome 220 is manufactured using silicon having a thixotropic index of about 2.7 to 3.3 (appropriately, 3.0), the optical dome 220 may include a dome ratio, indicating a ratio of a height of a dome to a diameter of a base of the dome (a height of the dome/a diameter of a base), of approximately 2.5 to 3.1 (appropriately 2.8). For example, the optical dome 220 formed of silicon having a thixotropic index of approximately 2.7 to 3.3 (appropriately, 3.0) may have a diameter of the base of approximately 2.5 mm and a height of approximately 0.7 mm.

The optical dome 220 may be optically transparent or translucent. Light emitted from the light-emitting diode 210 may be emitted to the outside by passing through the optical dome 220.

In this case, the dome-shaped optical dome 220 may refract light like a lens. For example, light emitted from the light-emitting diode 210 may be refracted by the optical dome 220 and thus may be dispersed.

As mentioned above, the optical dome 220 may disperse light emitted from the light-emitting diode 210 as well as protecting the light-emitting diode 210 from external mechanical and/or chemical or electrical actions.

Although not shown, a dissipative member (not shown) is formed near the optical dome 220 to protect the light-emitting diode 210 from electrostatic discharge. The dissipative member (not shown) may absorb an electric shock caused by electrostatic discharge generated near the optical dome 220.

Referring to FIG. 10, the light source module 110 may include the insulation layer 251 that is non-conductive, the conduction layer 252 laminated on a front surface of the insulation layer 251 and including the power supply line 230, and the protection layer 253 that is non-conductive and laminated on the front surface of the conduction layer 252. The insulation layer 251 may be referred to as a first layer, the conduction layer 252 as a second layer, and the protection layer 253 as a third layer, respectively.

The light-emitting diode 210 may be disposed on the protection layer 253. More particularly, the light-emitting diode 210 may be disposed on the front surface of the substrate 112 to cover the window formed on the protection layer 253.

The pair of power supply pads 240 may be formed on the conduction layer 252 and connected to the power supply line 230. The pair of power supply pads 240 may be electrically connected to the light-emitting diode 210 through the window formed on the protection layer 253. The pair of power supply pads 240 may be arranged to be separated from each other.

The light source module 110 may include a reflection-assisting layer 260a.

The reflection-assisting layer 260a may include a first portion 261a and a second portion 262a.

The first portion 261a may be disposed in a space between the pair of power supply pads 240. The first portion 261a may have a thickness corresponding to a thickness of the conduction layer 252. Particularly, a length of the first portion 261a extending along the front and rear direction may be provided to be equal to a thickness d1 of the conduction layer 252.

The second portion 262a may be disposed on the front side of the first portion 261a. The second portion 262a may be formed of the same material as the first portion 261a and may be formed together with the first portion 261a. The reflection-assisting layer 260a may include a White Photo Solder Resist (W-PSR) material having a high reflectance.

The second portion 262a may have a thickness corresponding to a thickness of the protection layer 253. Particularly, a length of the second portion 262a extending along the front and rear direction may be provided to be equal to a thickness d2 of the protection layer 253.

A width W1 of the first portion 261a of the reflection-assisting layer 260a may be provided to be equal to a width W2 of the second portion 262a, which is different from the light source according to one or more embodiments of the present disclosure shown in FIGS. 8 and 9. Particularly, a length in which the first portion 261a of the reflection-assisting layer 260a extends in the left and right direction may be equal to a length in which the second portion 262a extends in the left and right direction.

Further, in the light source illustrated in FIG. 10, the reflection-assisting layer 260a may be arranged so as not to cover the front surface of the pair of power supply pads 240. For example, the reflection-assisting layer 260a may be arranged between the pair of power supply pads 240 so as to form a separation space S between the pair of power supply pads 240.

Further, the widths W1 and W2 of the reflection-assisting layer 260a illustrated in FIG. 10 may be provided to be less than a gap P1 between the pair of power supply pads 240.

For example, the reflection-assisting layer 260a may be spaced apart from the pair of power supply pads 240 with respect to a width direction so as to be disposed between the pair of power supply pads 240.

Therefore, in the present disclosure, the luminance and Mura defects of the display apparatus may be improved by forming the reflection-assisting layer 260a in the empty space between the pair of power supply pads 240 and the conductive adhesive material 240a applied to the front surface of the pair of power supply pads 240.

Further, by forming the reflection-assisting layer 260a between the pair of power supply pads 240 at the same time as forming the protection layer 253, it is possible to reduce occurrence of a defect in which the sizes of the pair of power supply pads 240 exposed forward through the window of the protection layer 253 are formed asymmetrically.

In addition, when heat is applied to harden the optical dome 220, bubbles trapped in the empty space between the pair of power supply pads 240 may grow larger and cause Mura defects of the light source module 110 and the display apparatus 10. Therefore, according to the present disclosure, the space between the pair of power supply pads 240 and the space between the windows of the protection layer 253 may be filled with the reflection-assisting layer 260a to prevent the generation of bubbles. Accordingly, it is possible to contribute to the improvement of the overall Mura defects of the display apparatus 10 and the light source apparatus 100.

In addition, the light-emitting diode 210 may be disposed on the front surface of the substrate 112 so as to cover the entire open window of the protection layer 253. Accordingly, light traveling outward from the light-emitting diode 210 may be effectively reflected by the protection layer 253 without being absorbed by the conductive adhesive material 240a or the power supply pad 240, thereby improving the overall luminance and Mura defects.

While the disclosure has been illustrated and described with reference to one or more embodiments, it will be understood that the one or more embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiments described herein may be used in conjunction with any other embodiments described herein.

What is claimed is:

1. A light source apparatus comprising:
a reflective sheet comprising a hole formed therein; and
a light source module comprising:
a portion exposed through the hole;
a substrate comprising a non-conductive first layer, a second layer laminated on a front surface of the first layer and comprising a power supply line, and a third layer laminated on a front surface of the second layer;
a light-emitting diode on the third layer of the substrate;
a pair of power supply pads on the second layer, connected to the power supply line, and electrically connected to the light-emitting diode through a window on the third layer; and
a reflection-assisting layer in a space between the pair of power supply pads and comprising a first portion having a thickness corresponding to a thickness of the second layer and a second portion on a front side of the first portion and having a thickness corresponding to a thickness of the third layer.

2. The light source apparatus of claim 1, wherein a width of the first portion is less than a width of the second portion.

3. The light source apparatus of claim 2, wherein the second portion covers a portion of a front surface of the pair of power supply pads.

4. The light source apparatus of claim 2, wherein the width of the first portion is equal to the width of the second portion.

5. The light source apparatus of claim 4, wherein the reflection-assisting layer is between the pair of power supply pads and spaced apart from the pair of power supply pads with respect to a width direction.

6. The light source apparatus of claim 1, wherein a gap between the pair of power supply pads is 100 μm or less.

7. The light source apparatus of claim 1, wherein the window is between both sides of the second portion of the reflection-assisting layer and the third layer, and
wherein the pair of power supply pads are exposed in a forward direction via the window.

8. The light source apparatus of claim 1, wherein the light-emitting diode comprises a Distributed Bragg Reflector (DBR) layer.

9. The light source apparatus of claim 8, wherein light emitted from the light-emitting diode is reflected by the DBR layer and re-reflected by the reflection-assisting layer.

10. The light source apparatus of claim 1, wherein the third layer comprises a White Photo Solder Resist (W-PSR) material.

11. The light source apparatus of claim 1, wherein the reflection-assisting layer is the same material as the third layer, and
wherein the third layer is between the pair of power supply pads.

12. The light source apparatus of claim 1, wherein the reflection-assisting layer contacts the front surface of the first layer and is configured to prevent light emitted from the light-emitting diode from being absorbed by the first layer.

13. The light source apparatus of claim 1, wherein the first layer is a non-conductive insulation layer, the second layer is a conductive conduction layer, and the third layer is a non-conductive protection layer.

14. The light source apparatus of claim 1, further comprising:
a conductive adhesive material on the window and parallel to the second portion of the reflection-assisting layer, and configured to electrically connect the pair of power supply pads to the light-emitting diode.

15. The light source apparatus of claim 1, wherein the light-emitting diode is on a front surface of the substrate and covers the window entirely.
